(19) United States
(12) Patent Application Publication
(10) Pub. No.: US 2025/0218905 A1
(43) Pub. Date: Jul. 3, 2025

(54) COMPONENT COUPLED WITH CONDUCTIVE VIAS ENCAPSULATED IN AN ELECTRONIC SUBSTRATE

(71) Applicant: Intel Corporation, Santa Clara, CA (US)

(72) Inventors: Jeremy Ecton, Gilbert, AZ (US); Brandon Marin, Gilbert, AZ (US); Srinivas Pietambaram, Chandler, AZ (US); Gang Duan, Chandler, AZ (US); Suddhasattwa Nad, Chandler, AZ (US)

(73) Assignee: Intel Corporation, Santa Clara, CA (US)

(21) Appl. No.: 18/401,025

(22) Filed: Dec. 29, 2023

(51) Int. Cl. H01L 23/482; H01L 23/00; H01L 23/498; H01L 25/065

(52) U.S. Cl. CPC H01L 23/4821; H01L 23/49816; H01L 23/49822; H01L 24/05; H01L 24/29; H01L 25/0652; H01L 2224/05024; H01L 2224/05025; H01L 2224/29009; H01L 2224/29021; H01L 2924/01029; H01L 2924/1431; H01L 2924/1434; H01L 2924/15311; H01L 2924/182

(57) ABSTRACT

An apparatus includes a substrate, a cavity within the substrate, and a die within the cavity. The substrate has an exterior surface. The cavity includes a first surface and a second surface opposite the first surface. The die includes a discrete component, a first side, a second side opposite the first side, and conductive features at the first side. In an embodiment, a bond film is between the first surface and the first side. A plurality of conductive vias extend from the exterior surface through the substrate and bond film to the conductive features. In an embodiment, the bond film may be omitted. The plurality of conductive vias extend from the exterior surface through the substrate. The conductive features of the die are coupled with the conductive vias by solder features, and the second side of the die is spaced away from the second surface.

### BACKGROUND

In electronics manufacturing, integrated circuit (IC) packaging is a stage of semiconductor device fabrication in which an IC that has been monolithically fabricated on a chip (or die) is assembled into a “package” that can protect the IC chip from physical damage. The package can also communicatively connect the IC chip to other packaged IC chips and/or a scaled host component, such as a package substrate, or a printed circuit board. Multiple IC chips can be co-assembled, for example, into a multi-die package (MCP).

In addition to IC chips, some IC packages architectures include capacitors or other components on the die or land side of a host component. These components may be used, for example, in voltage regulation circuitry. However, the space available on the sides of a host component is limited. Including a capacitor or other device on a side of a package substrate of a particular size may reduce the number of IC chips that can assembled in a multiple IC chip package. Alternatively, the size of the package substrate may need to be increased to accommodate a desired number of IC chips.

### BRIEF DESCRIPTION OF THE DRAWINGS

The subject matter described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Views referred to as “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure. Further, where considered appropriate, reference labels have been repeated among the figures to indicate corresponding or analogous elements. In the figures:

FIGS. 1A and 1B illustrate a flow diagram of methods for forming an IC device package including a die within a cavity in a substrate, a bond film between the die and a surface of the cavity, and a plurality of self-aligned interconnects, in accordance with some embodiments;

FIGS. 2A through 2L illustrate cross-sectional views of a workpiece evolving into an IC device package including a die within a cavity in a substrate, a bond film between the die and a surface of the cavity, and a plurality of self-aligned interconnects as selected operations in the methods illustrated in FIGS. 1A and 1B are performed, in accordance with some embodiments;

FIG. 3 illustrates a system including the IC device package structure illustrated in FIG. 2L attached to a host component with solder features, in accordance with some embodiments;

FIG. 4 illustrates a cross-sectional view of a die comprising a capacitor, according to an example;

FIG. 5 illustrates a flow diagram of methods for forming an IC device package including a die within a cavity in a substrate, the die having conductive features coupled with conductive vias through the substrate by solder features, wherein a second side of the die is spaced away from a surface of the cavity, in accordance with some embodiments;

FIGS. 6A through 6I illustrate cross-sectional views of a workpiece evolving into an IC device package including a die within a cavity in a substrate, the die having conductive features coupled with conductive vias through the substrate by solder features, wherein a second side of the die is spaced away from a surface of the cavity as selected operations in the methods illustrated in FIG. 5 are performed, in accordance with some embodiments;

FIG. 7 illustrates a system including the IC device package structure illustrated in FIG. 6H attached to a host component with solder features, in accordance with some embodiments;

FIG. 8 illustrates a mobile computing platform and a data server machine employing one or more of IC device package structures illustrated in FIG. 2L and/or FIG. 6H, and/or one or more of the systems illustrated in FIG. 3 and/or FIG. 7, in accordance with some embodiments; and

FIG. 9 is a functional block diagram of an electronic computing device employing one or more of IC device package structures illustrated in FIG. 2L and/or FIG. 6H, and/or one or more of the systems illustrated in FIG. 3 and/or FIG. 7, in accordance with some embodiments.

### DETAILED DESCRIPTION

Embodiments are described with reference to the enclosed figures. While specific configurations and arrangements are depicted and discussed in detail, this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that embodiments may be practiced without these specific details. In some instances, well-known methods and devices are shown in block diagram form, rather than in detail, to avoid obscuring the embodiments. Reference throughout this specification to “an embodiment” or “one embodiment” or “some embodiments” means that a particular feature, structure, function, or characteristic described in connection with the embodiment is included in at least one embodiment. Thus, the appearances of the phrase “in an embodiment” or “in one embodiment” or “some embodiments” in various places throughout this specification are not necessarily referring to the same embodiment. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description and the appended claims, the singular forms “a”, “an” and “the” are intended to include the plural forms as well, unless the context clearly indicates otherwise. It will also be understood that the term “and/or” as used herein refers to and encompasses all possible combinations of one or more of the associated listed items.

The terms “coupled” and “connected,” along with their derivatives, may be used herein to describe functional or structural relationships between components. These terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause-and-effect relationship).

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer is in direct physical contact with that second material/layer. Similar distinctions are to be made in the context of component assemblies.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C.

Unless otherwise specified in the specific context of use, the term “predominantly” means more than 50%, or more than half. For example, a composition that is predominantly a first constituent means more than half of the composition is the first constituent (e.g., <50 at. %). The term “primarily” means the most, or greatest, part. For example, a composition that is primarily a first constituent means the composition has more of the first constituent than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

It may be an advantage to incorporate passive components of voltage regulation circuitry into the substrate core of an integrated circuit (IC) device package. For example, a pick and place tool can place a discrete passive component, e.g., a deep trench capacitor (DTC), into a cavity of the substrate core. After placement, the component may be encapsulated with dielectric or mold. For discrete passive components fabricated using silicon technology, the thickness of the component is typically limited by the thickness of the silicon wafer and other process limitations. As a consequence, the thickness of the substrate core may be greater than the thickness of the die containing the passive component to be placed in the cavity. The limited thickness of discrete passive components can be a problem. Specifically, a discrete passive component may shift and/or rotate within the cavity in the core during and after the encapsulation process. Component movement can result in problems with electrical interconnects between the component and contacts at a surface of the cavity.

IC device package structures including a substrate, a cavity within the substrate, and a die within the cavity are described herein. The substrate includes a plurality of conductive vias extending between an exterior surface of the substrate and a surface of the cavity. The die includes a plurality of conductive features at a side of the die facing the surface of the cavity. The die may include a discrete component, such a capacitor.

In some embodiments, a bond film is disposed between the side of the die and the surface of the cavity. In embodiments that include a bond film, the plurality of conductive vias not only extend through the substrate, they also extend through the bond film. More specifically, each conductive via includes first and second portions. The first portion extends through the substrate, and the second portion extends through the bond film and contacts one of the conductive features on the die. The conductive vias may be self-aligned vias or interconnects. The bond film may be a conformal bond film, although a conventional bond film may be used in some embodiments.

In other embodiments, the bond film may be omitted and the plurality of conductive vias only extend through the substrate. In embodiments in which the bond film is omitted, the conductive features of the die are coupled with the conductive vias by solder features. The conductive vias extend to a first surface of the cavity, and the cavity includes a second surface opposite the first surface. In embodiments, the plurality of conductive features on the die are at first side of the die, the die includes a second side opposite to first side, and the second side of the die is spaced away from the second surface.

Embodiments disclosed herein provide advantages for die placed in a cavity of a substrate core where the die is thinner than the core, or where the die that has a height less than, or in some embodiments approximately equal to, a depth of a cavity in the substrate core. Advantages include minimizing or eliminating shifting and/or rotating of the die during and after an encapsulation process, which can reduce or eliminate problems with electrical interconnects to the die. Another advantage is that mold or dielectric encapsulation may be omitted because the die is secured by bond film or solder features. Furthermore, the die is protected, as it is hermitically sealed within the cavity.

Embodiments disclosed herein may include an electrical routing structure comprising redistribution layer (RDL) metallization that may be built-up on at least one side of the substrate, and IC die(s) assembled to the routing structure.

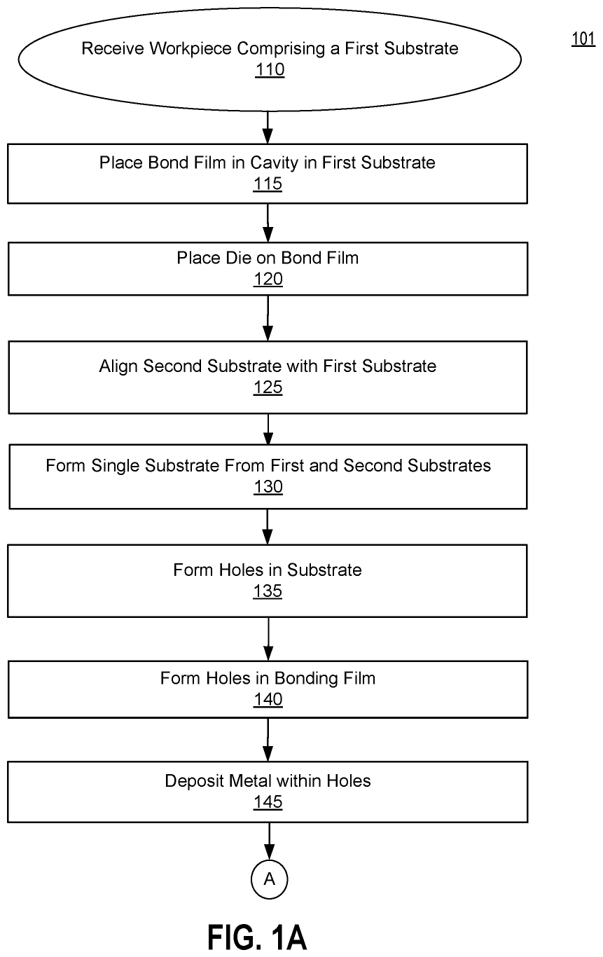

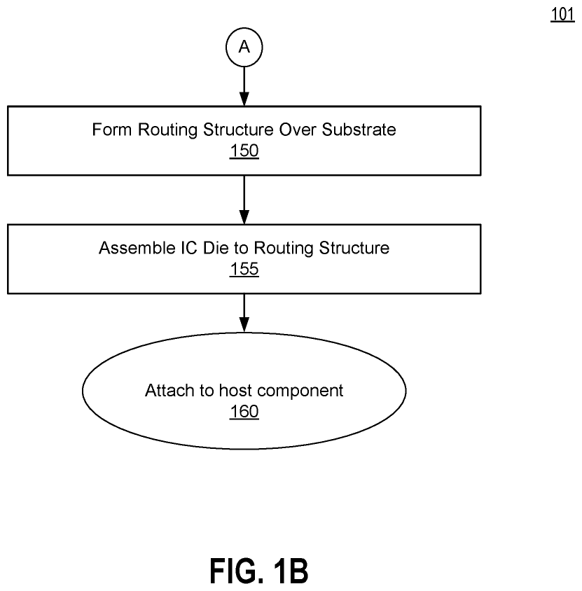

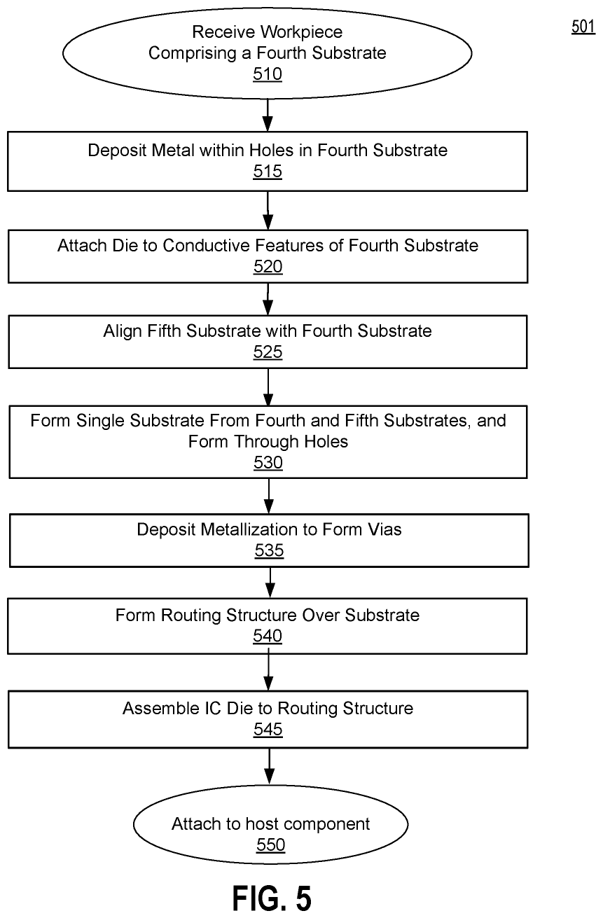

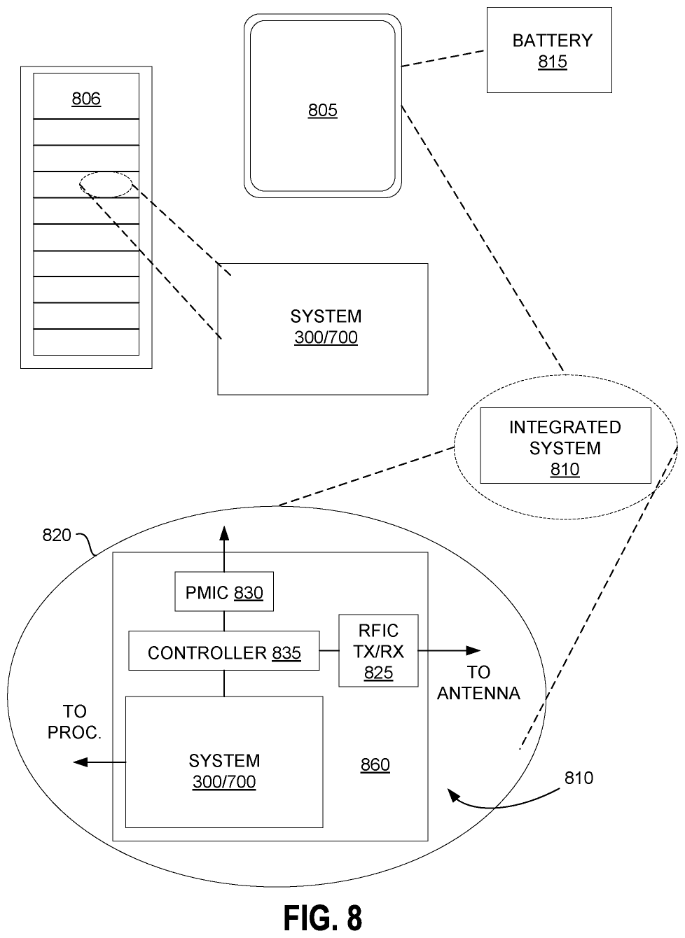

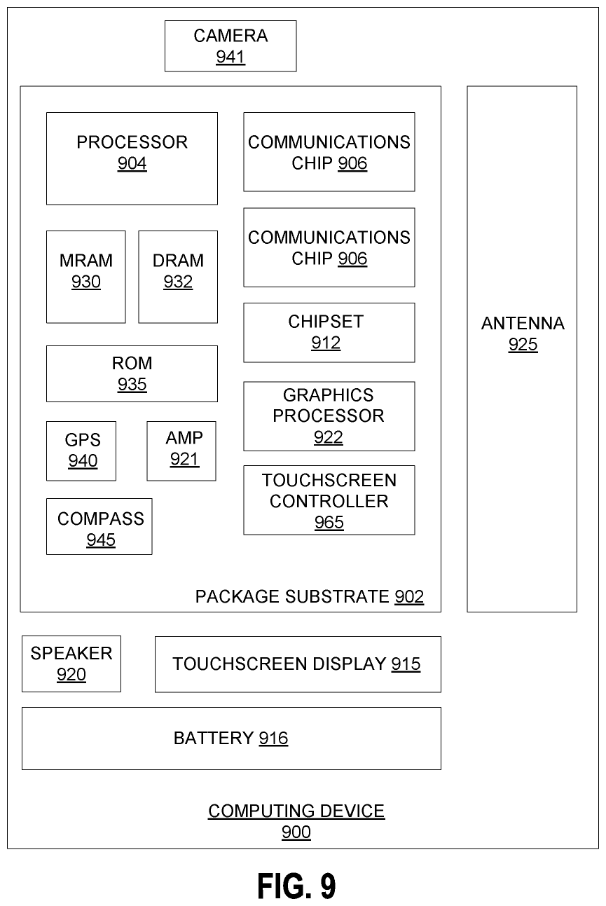

Embodiments that include a bond film are described with reference to FIG. 1A to FIG. 3. Embodiments that do not include a bond film are described with reference to FIG. 5 to FIG. 7. Embodiments described with reference to FIG. 8 and FIG. 9 may use any of the IC device package structures and systems described herein.

As illustrated in FIGS. 1A and 1B, a variety of fabrication methods may be practiced to form IC device package structures having one or more of the features described herein. FIGS. 1A and 1B illustrate a flow diagram of methods 101 for forming an IC device package structure including a die within a cavity in a substrate, a bond film between the die and a surface of the cavity, and a plurality of self-aligned interconnects comprising a first portion through the substrate and a second portion through the bond film, in accordance with some embodiments. Methods 101 begin at input 110 where a workpiece including a first substrate is received. The workpiece may be prepared upstream of methods 101 and may be in a large panel format, a wafer format, or the like. In some embodiments, the first substrate comprises one or more organic materials, e.g., epoxy. The organic material(s) may include fillers, e.g., glass cloth or fibers. In some embodiments, the first substrate comprises glass.

In embodiments in which the substrate comprises glass, the glass is a solid bulk material layer that may have been previously formed into any shape in plan view (e.g., x-y plane) suitable for a packaging workpiece, such as rectangular. The glass is advantageously predominantly silicon and oxygen. In some embodiments, the glass comprises at least 23 percent silicon and at least 26 percent oxygen, by weight (i.e., wt. %). The glass may further include one or more additives, such as, Aluminum, Boron, Magnesium, Calcium, Barium, Tin, Sodium, Potassium, Strontium, Phosphorus, Zirconium, Lithium, Titanium, or Zinc. In some embodiments where glass comprises at least 23 wt. % Si and at least 26 wt. % 0, the glass further comprises at least 5 wt. % Al. Additives within the glass may form suboxides (A2O) monoxides (AO), binary oxides (AO2), ternary oxides (ABO3), and mixtures thereof. For example, the glass may comprise AlOx (e.g., Al₂O₃), BOx (e.g., B2O3), MgOx (e.g., MgO), CaOx (e.g., CaO), SrOx (e.g., SrO), BaOx (e.g., BaO), SnOx (e.g., SnO2), NaOx (e.g., Na2O), KOx (e.g., K2O), POx (e.g., P2O3), ZrOx (e.g., ZrO2), LiOx (e.g., Li2O), TiOx (e.g., TiO2), or ZnOx (e.g., ZnO2). Depending on chemical composition, the glass may therefore be referred to as silica, fused silica, aluminosilicate, borosilicate, or alumino-borosilicate, for example.

In embodiments in which the substrate comprises glass, the glass is advantageously a bulk material of substantially homogeneous composition in contrast to a composite material that may merely comprise glass fillers and/or fibers. Although the glass is substantially amorphous in some embodiments, the glass may also have other morphology or microstructure, such as polycrystalline (e.g., nanocrystalline).

Although not depicted, in embodiments in which the substrate comprises glass, one or more material layers may clad either or both of the front-side surface or back-side surface of the substrate so that glass is a bulk or core layer of a multi-layered substrate. Exemplary cladding materials include inorganic materials such as silicon nitride (SiNx) or silicon oxynitride (SiOxNy). In other embodiments, a silicon layer (polycrystalline or monocrystalline) may clad one or both sides of the glass. Organic material layers, such as polymer dielectric materials, may also clad one or more sides of the glass. Hence, while the glass is advantageously substantially free of organic materials (e.g., no adhesives, etc.), a workpiece may include organic material within a substrate stack that includes glass.

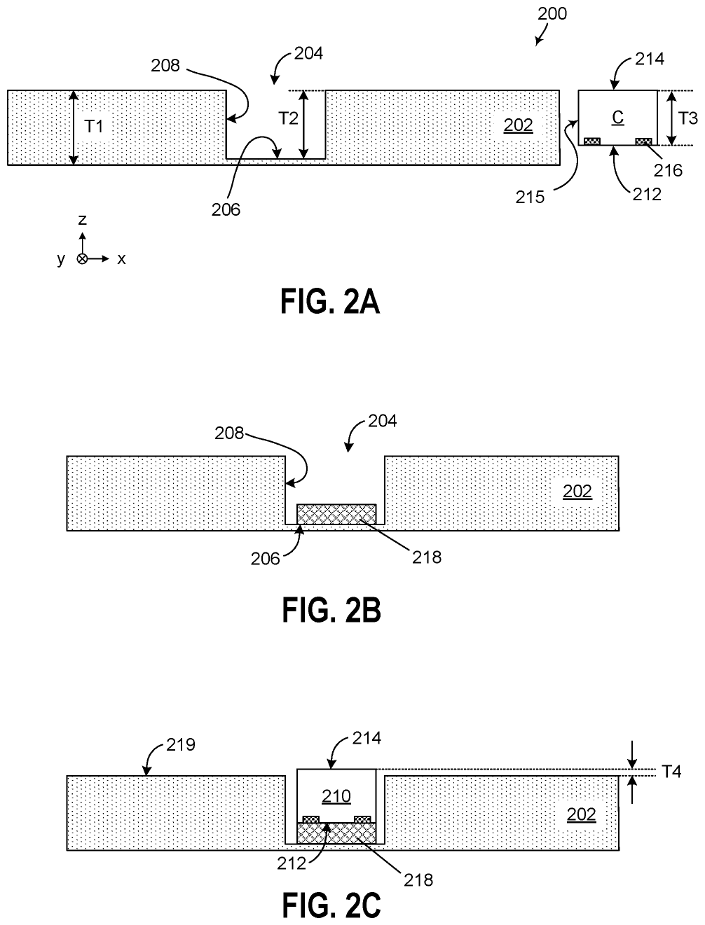

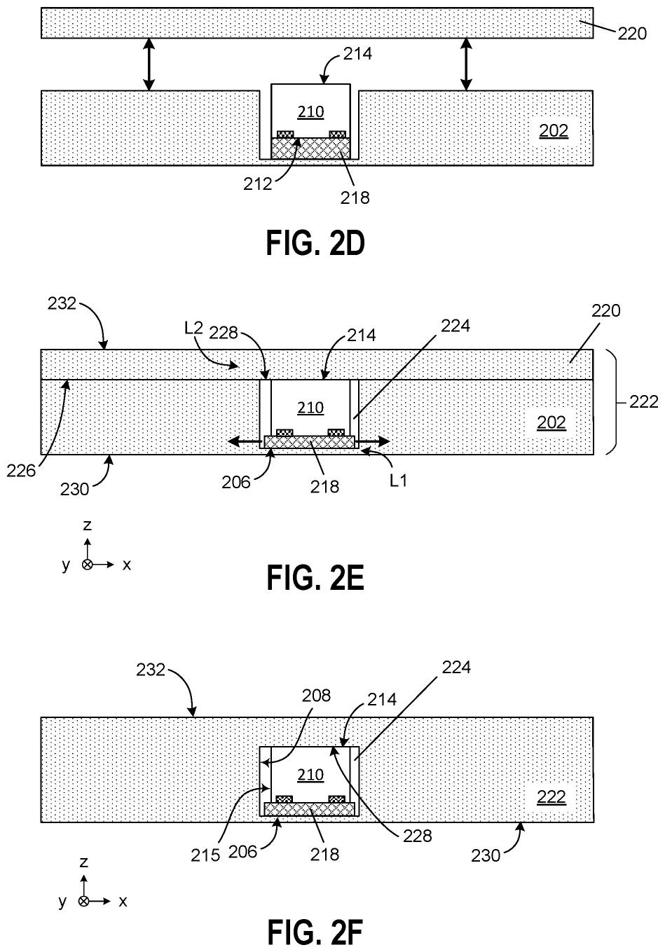

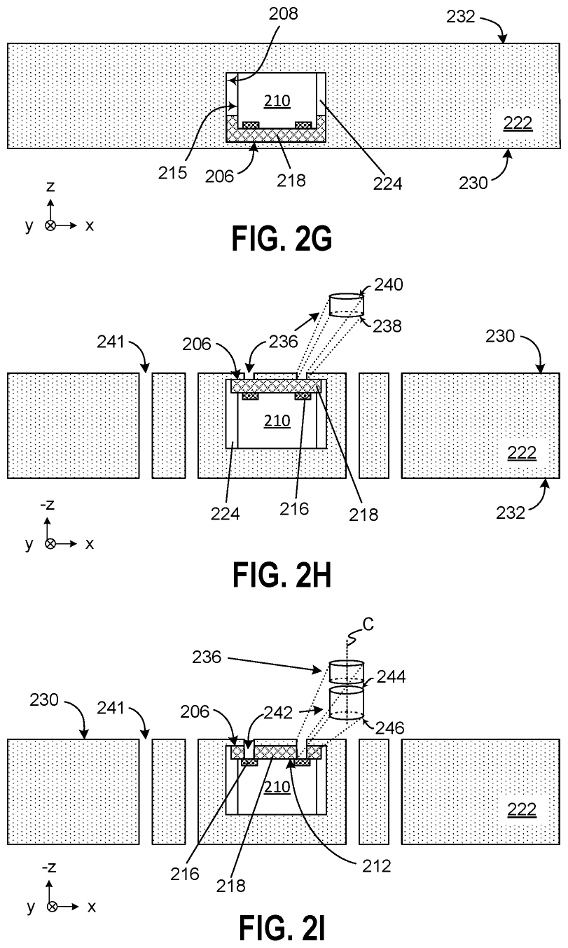

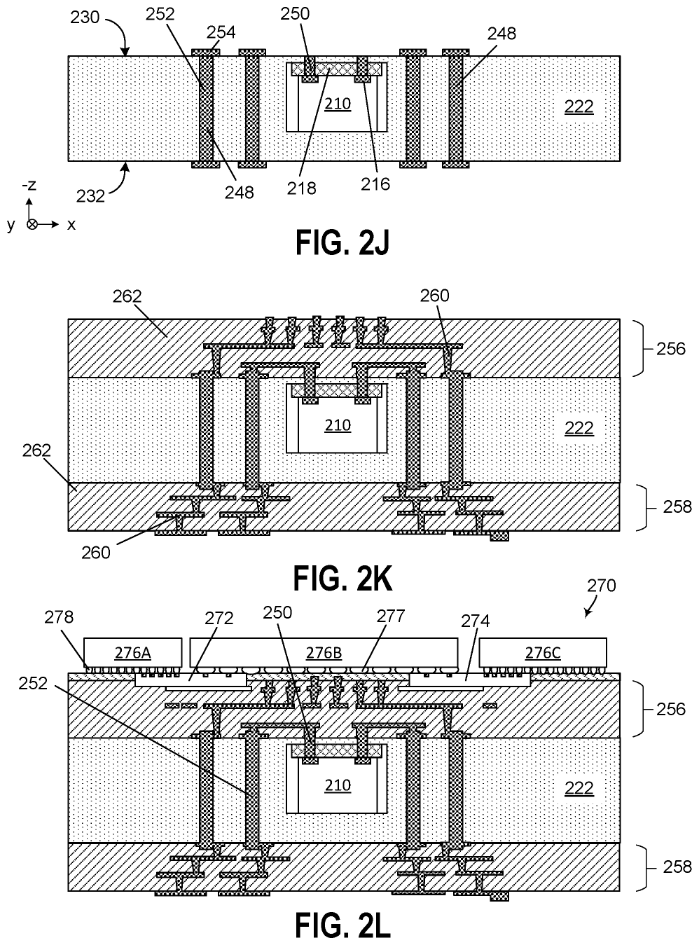

FIG. 2A is a cross-sectional view of an exemplary workpiece 200 including a first substrate 202. First substrate 202 is a solid bulk material layer that may have been previously formed into any shape suitable for a packaging workpiece, such as rectangular. First substrate 202 has a thickness T1 that may vary with implementation. In embodiments, thickness T1 may be as low at 50 μm, but is typically at least 100 μm up to about 2000 μm. First substrate 202 includes an open cavity 204, which has a depth T2 that is less than the thickness T1. In embodiments, depth T2 may be about 50 μm up to about 2000 μm. Cavity 204 includes a first surface 206 and sidewalls 208. FIG. 2A also illustrates a die 210 intended for placement in cavity 204. As shown in FIG. 2A, die 210 comprises a first side 212 and a second side 214 opposite the first side. Die 210 has sidewalls 215 that extend between first side 212 and second side 214. Die 210 includes conductive features 216, e.g., metal pads or contacts, at first side 212. Die 210 has a thickness T3 that is less than the depth T2 of the cavity 204. Die thickness T3 and cavity depth T2 may be approximately equal, provided cavity depth T2 is greater so that there is sufficient space for bond film, solder, underfill, etc. Die thickness T3 is typically 50 μm to 600 μm, however, in some embodiments, die thickness T3 may be about 50 μm to about 2000 μm. Die 210 may include deep trench capacitor in some embodiments.

Returning to FIG. 1A, methods 101 continue at block 115 where a bond film is placed on a surface of the cavity. The surface may be a bottom interior surface opposite a cavity opening. The bond film may be a conformal bond film, although a conventional bond film may be used in some embodiments. A conformal bond film may comprise a low filler buildup film (e.g., with a filler percentage that is less than 30%), a liquid buildup film, or polydimethylsiloxane (PDMS) or the like. The bond film may also be a hybrid or multilayered film consisting of conventional bond film material and the previously mentioned materials. A conventional bond film may comprise epoxy, polymer, or a dielectric. In some embodiments, a solder (e.g., tin or tin alloys (such as a high melting point Sn/Au, etc.)) can also be used wherein solder is placed on backside of the die and pressed under heat (above melting point of solder), followed by a cooling step to fix the die in place. The bond film may be dispensed on the backside of the die and may only be in contact with the backside of the die. FIG. 2B is a cross-sectional view of workpiece 200 after a bond film 218 has been placed on first surface 206 in open cavity 204 of first substrate 202.

Returning to FIG. 1A, methods 101 continue at block 120 where a die is placed on the bond film in the open cavity in the first substrate. FIG. 2C is a cross-sectional view of workpiece 200 after a die 210 has been placed on the bond film in the open cavity in the first substrate. After placement, first side 212 of die 210 contacts the bond film 218. The combined height of bond film 218 and the die 210 is greater than depth T2 of open cavity 204, such that the second side 214 of die 210 is stands above a top surface 219 of first substrate 202 by a distance T4. In embodiments, the die 210 may be the same as or similar to die 400, described below. In some embodiments, die 210 may include any discrete component other than a capacitor, such as an inductor, resistor, transistor, diode, or optical switch.

FIG. 4 illustrates a cross-sectional view of a die 400 comprising a capacitor, according to one example. In an embodiment, die 400 may comprise a deep trench capacitor (DTC). The example die 400 includes conductive contacts 402a and 402b. Conductive contact 402a is electrically coupled with metal structure 404a. Conductive contact 402b is electrically coupled with metal structure 404b. Metal structures 404a and 404b are separated by a dielectric 405. Die 400 may include solder features 406 on conductive contacts 402a and 402b.

Returning to FIG. 1A, methods 101 continue at block 125 where a second substrate is aligned with the first substrate in preparation to be placed on and attached to the first substrate. In some embodiments, the second substrate is comprised of the same material as the first substrate. In some embodiments, the second substrate is comprised of a different material than the first substrate. FIG. 2D is a cross-sectional view of workpiece 200 illustrating a second substrate 220 positioned over and aligned with first substrate 202.

Returning to FIG. 1A, methods 101 continue at block 130 where the first and second substrates are formed into a single substrate having a closed cavity. At block 130, the first and second substrates are placed in contact with one another, and attached to one another. The first and second substrates may be attached in suitable manner known in the art. For example, a bonding film or other adhesive layer between the first and second substrates may be used to bond the two substrates together. Pressure, heat, or both pressure and heat may be used in conjunction with use of a bonding film or adhesive layer. In some examples, the bonding film or adhesive may be omitted, and pressure, heat, or both pressure and heat, alone may be used.

FIG. 2E is a cross-sectional view of workpiece 200 after second substrate 220 has been placed onto first substrate 202. Fusing or bonding first and second substrates 202, 220 results in the formation of a single substrate 222 having a closed cavity 224. In some embodiments, the single substrate 222 may have a seam 226 at the interface where the first and second substrates 202, 220 are fused or bonded together. As second substrate 220 is placed into the contact with first substrate 202, the second substrate 220 first contacts die 210, pushing it down (−z-direction). In its final position, second substrate 220 may remain in contact with the second side 214 of die 210. Closed cavity 224 has a second interior surface 228, which is opposite the first interior surface 206 of the cavity. Pressing the substrates together causes bonding film 218 to compress or vertically contract (in the −z-direction) and expand laterally (in +/−x-direction), as indicated by the arrows in FIG. 2E. The substrate 222 has a first exterior surface 230, and a second exterior surface 232 opposite the first surface 230. In some embodiments, the second surface 228 contacts second side 214 of die 210 after the third die has been formed. Second substrate 220 may have a minimum thickness of about 50 μm. Single substrate 222 may have a thickness ranging from about 100 μm to about 2000 μm. Bonding film 218, after being compressed as shown in FIG. 2E, may have a thickness ranging from about 1 μm to about 10 μm.

Still referring to FIG. 2E, a first layer L1 is between the first interior surface 206 of closed cavity 224 and first exterior surface 230 of substrate 222. A second layer L2 is between the second exterior surface 232 of substrate 222 and the second surface 228 of cavity 224. The second layer L2 may correspond with a portion of second substrate 220 proximate die 210. In some embodiments, die 210 is within the substrate 222 between the first layer L1 and second layer L2.

FIG. 2F is a cross-sectional view of workpiece 200 after second substrate 220 has been fused or bonded onto first substrate 202. In some embodiments, after the first and second substrates 202, 220 have been fused or bonded together, there may not be a seam 226 at the bonding interface, as the example in FIG. 2F illustrates. After the first and second substrates 202, 220 have been fused or bonded together, sidewall 215 of die 210 may be spaced away from a proximate sidewall 208 of closed cavity 224. In embodiments, a region between sidewall 215 and sidewall 208 comprises one or more inert gases, e.g., helium, neon, argon, krypton, xenon, or radon, but may include other gasses, such as nitrogen, oxygen, carbon dioxide, methane, nitrous oxide, ozone, etc. In some embodiments, the region between sidewall 215 and sidewall 208 comprises a vacuum. In some embodiments, bond film 218, after being compressed, partially fills the region between sidewall 215 and sidewall 208, occupying the region by a distance from about 1 μm to about 10 μm above first surface 206. The region between sidewall 215 and sidewall 208 may be referred to as an “air gap.” In embodiments, second side 214 of die 210 contacts second surface 228 of cavity 224. Although not depicted in FIG. 2E or FIG. 2F, in some embodiments, the second surface 228 may be spaced away from the second side 214 of die 210 after the third die has been formed. For example, in an embodiment in which the compressibility of the bonding film 218 is minimal. In these examples, there may be an “air” gap between second side 214 and second surface 228.

FIG. 2G is another example of workpiece 200 after second substrate 220 has been fused or bonded with first substrate 202. In the cross-sectional view of FIG. 2G, it can be seen that pressing first and second substrates 202, 220 together may cause bonding film 218 to expand into a region between sidewall 215 of die 210 and a proximate sidewall 208 of closed cavity 224. Accordingly, the region between sidewall 215 and sidewall 208 can include a solid material, e.g., bonding film 218.

Returning to FIG. 1A, methods 101 continue at block 135 where holes are formed in the substrate, e.g., the single substrate resulting from the bonding or fusing first and second substrates. The holes may be fabricated with any process known to be suitable for the substrate material. In embodiments, block 135 may entail laser ablation, a glass etch process (laser-assisted, or otherwise), or any other technique known to be suitable for forming holes in a glass substrate. In embodiments, block 135 may include forming holes using a mechanical tool, such as a drill, a laser, or any other technique known to be suitable for forming holes in organic materials, with or without fillers.

FIG. 2H is a cross-sectional view of workpiece 200 after first holes 236 have been formed through the substrate 222 over conductive features 216 of die 210. Substrate 222 and die 210 are inverted in FIG. 2H compared to the depiction in FIG. 2G. The first holes 236 extend from first surface 230 on the exterior of substrate 222 to the first surface 206 on the interior of closed cavity 224. Each first hole 236 includes a first opening 238 in the substrate 222 at the first surface 206 of the closed cavity 224. Each first hole 236 also includes a second opening 240 in the substrate 222 at the first surface 230 of substrate 222. First holes 236 may be any shape in the y-z plane, e.g., round, oval, rectangular, and the like. Similarly, first and second openings 238, 240 may be any shape in the y-z plane. FIG. 2H also illustrates third holes 241 having been formed through the substrate 222 between first surface 230 and second surface 232.

Returning to FIG. 1A, methods 101 continue at block 140 where holes are formed in the bonding film. The holes may be fabricated with any known, suitable process. In embodiments, formation of holes in the bonding film may include any suitable process for removing the bonding film, e.g., dry etch or plasma etch process. The first holes 236 in substrate 222 serve as a mask for the bond film removal process. Use of the first holes 236 as a mask results in second holes that are “self-aligned” with the first holes 236. As a result of the self-alignment technique, centers of the first holes are directly aligned with centers of the second holes. Furthermore, as a result of using the first holes 236 as a mask, adjacent openings of the first holes and second holes are aligned and have substantially the same shape in the y-z plane.

FIG. 2I is a cross-sectional view of workpiece 200 after second holes 242 have been formed through the bonding film 218 over conductive features 216 of die 210. Each second hole 242 extends through the bond film 218 between one of the conductive features 216 and first surface 206 of closed cavity 224. As can be seen in FIG. 2I, a center of the first hole 236 is directly aligned with a center of the second hole 242, as illustrated by center line C. Each second hole 242 includes a top opening 244 in the bond film 218 at the first surface 206 of the closed cavity 224. Each second hole 242 also includes a bottom opening 246 in the bond film 218 at the first side 212 of die 210 (at a conductive feature 216). In an embodiment, at least one first opening 238 in substrate 222 is aligned with and has substantially the same shape as top opening 244 in bond film 218.

First holes 236 extend through substrate 222 and second holes 242 extend through the bonding film 218. In embodiments, the first holes are directly aligned with the second holes. Each pair of first and second holes join to form a single hole. As such, a first hole 236 may that may be referred to herein as a first portion of the single hole. Similarly, a second hole 242 may be referred to herein as a second portion of the single hole.

Returning to FIG. 1A, methods 101 continue at block 145 where a suitable metal is deposited within the holes to form electrically conductive vias. Operations at block 145 may include planarizing the via metallization to remove overburden associated with the plating process. Operations at block 145 may include forming pads or contacts on exterior surfaces of the substrate.

FIG. 2J is a cross-sectional view of workpiece 200 after a via metallization 248 has been deposited to form first vias 250 and second vias 252. First vias 250 extend through both substrate 222 and bond film 218. First vias 250 may be in direct contact with conductive features 216 of die 210. First vias 250 extend to first surface 230, where they may or may not comprise a pad or contact on first surface 230. Second vias 252 extend through substrate 222 between first exterior surface 230 and second exterior surface 232. Second vias 252 may be referred to as through-substrate vias (TSVs) or, in some embodiments, through-glass vias (TGVs). Second vias 252 may include a pad or contact 254 on first surface 230, second surface 232, or on both surfaces. Pads or contacts on first and second surfaces, 230, 232 may be added at block 145 or at a later stage of processing. The first vias 250 may be formed by electroplating first holes 236 and second holes 242. As each first and second hole 236, 242 is a single hole, it may be said that the via 250 is formed by electroplating the first portion and second portion of the single hole. The second vias 252 may be formed by electroplating holes third holes 241. In some examples, via metallization 248 is one or more metals (e.g., predominantly copper) deposited (e.g., electroplated) upon surfaces of the holes and substrate.

Returning to FIG. 1, methods 101 continue at block 150 where an electrical routing structure is built up over at least one side of the substrate prior to assembly with one or more IC die external to the substrate. The electrical routing structure may be electrically coupled to the vias and may, for example, comprise one or more levels of metallization features embedded within any suitable dielectric material. The electrical routing structure formed at block 150 may interconnect one or more IC die external to the substrate to each other and/or couple one or more of these IC die to the conductive vias. Moreover, the electrical routing structure formed at block 150 may interconnect one or more IC die external to the substrate to a die within a cavity in the substrate. Electrical routing structures may be formed on one or both exterior surfaces of the substrate.

FIG. 2K is a cross-sectional view of workpiece 200 after a first routing structure 256 has been built-up over first surface 230 of substrate 222, and a second routing structure 258 has been built-up over second surface 232. Routing structures 256, 258 comprise one or more levels of redistribution layer (RDL) metallization features 260 embedded within one or more layers of dielectric material 262. RDL metallization features 260 may comprise one or more metals, with one example being predominantly copper. At least some of RDL metallization features 260 are to electrically couple die 210 with circuitry elsewhere in the substrate or with an IC die coupled with the substrate in an IC device package.

Depending on the embodiment, dielectric material 262 may be any of a molding compound, a spin-on material, or dry film laminate material, for example. Dielectric material 262 may be introduced wet/uncured into a cast and then dried/cured. Alternatively, dielectric material 262 may be introduced as a semi-cured dry film that is fully cured following its application to substrate 222.

The composition of dielectric material 262 may vary with implementation. In some advantageous embodiments, dielectric material 262 is an organic dielectric, such as, an epoxy resin, phenolic-glass, or a resinous film such as the GX-series films commercially available from Ajinomoto Fine-Techno Co., Inc. (ABF). Dielectric material 262 may comprise epoxy resins (e.g., an acrylate of novolac such as epoxy phenol novolacs (EPN) or epoxy cresol novolacs (ECN)). In some specific examples, dielectric material 262 is a bisphenol-A epoxy resin, for example including epichlorohydrin. In other examples, dielectric material 262 includes aliphatic epoxy resin.

Returning to FIG. 1, methods 101 continue at block 155 where at least one IC die is assembled to the workpiece and, more particularly, to the electrical routing structure that was formed at block 150. IC die assembled at block 155 may each comprise any electrical circuitry, with one example being logic circuitry comprising logic gates. IC die assembled at block 155 may also comprise any photonic circuitry suitable for the detection, emission or processing (e.g., filtering, multiplexing and demultiplexing) of optical signals.

FIG. 2L is a cross-sectional view of workpiece 200 after IC bridge die 272 and 274 are assembled to interconnect interfaces within a top metallization level of routing structure 256 of a co-packaged multi-die IC device package structure 270. In the example of FIG. 2L, IC die 276A, 276B, and 276C are assembled to interconnect interfaces within a top metallization level of routing structure 256 and to the bridge IC die. IC bridge die 272 and 274 may be directly bonded to routing structure 256, or, electrically coupled through intervening electrical interconnects, which may comprise solder of any suitable composition. In the example illustrated in FIG. 2L, IC die 276A, 276B, and 276C may be electrically coupled to the IC bridge die through intervening electrical interconnects 277, 278, which may comprise solder of any suitable composition. IC die 276A, 276B, and 276C are each flip-chip attached with integrated circuitry within each die.

Each of IC die 276A, 276B, and 276C may be a fully functional ASIC, or may be a chiplet or tile that has more limited functionality supplementing the function of one or more other IC dies that are to be part of the same multi-die device. A chiplet or tile may, for example, be any of a wireless radio circuit, microprocessor core, electronic memory circuit, floating point gate array (FPGA), power management and/or power supply circuit, or include a MEMS device. In some examples, one or more of IC die 276A, 276B, and 276C include one or more banks of active repeater circuitry to improve multi-die interconnects (e.g., network-on-chip architectures). In other examples, one or more of IC die 276A, 276B, and 276C includes clock generator circuitry or temperature sensing circuitry. In other examples, one or more of IC die 276A, 276B, and 276C include logic circuitry that, along with other IC die 276A, 276B, and 276C implement multi-chiplet aggregated logic circuitry (e.g., mesh network-on-chip architectures). In some specific examples, at least one of IC die 276A, 276B, and 276C includes microprocessor core circuitry, for example comprising one or more shift registers.

IC die 276A, 276B, and 276C advantageously comprise field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, IC die 276A, 276B, and 276C may include active devices other than FETs. For example, IC die 276A, 276B, and 276C may include electronic memory structures, such as magnetic tunnel junctions (MTJs), capacitors, or the like.

IC die 276A, 276B, and 276C may comprise one or more IC die metallization levels embedded within an insulator. While the IC die metallization features may have any composition(s) of sufficient electrical conductivity, in exemplary embodiments, the IC die metallization features are predominantly copper (Cu). In other examples, the metallization features are predominantly other than Cu, such as, but not limited to predominantly Ru, or predominantly W. An uppermost one of the metallization features within IC die 276A, 276B, and 276C may have a feature pitch ranging from 100 nm to several microns, for example.

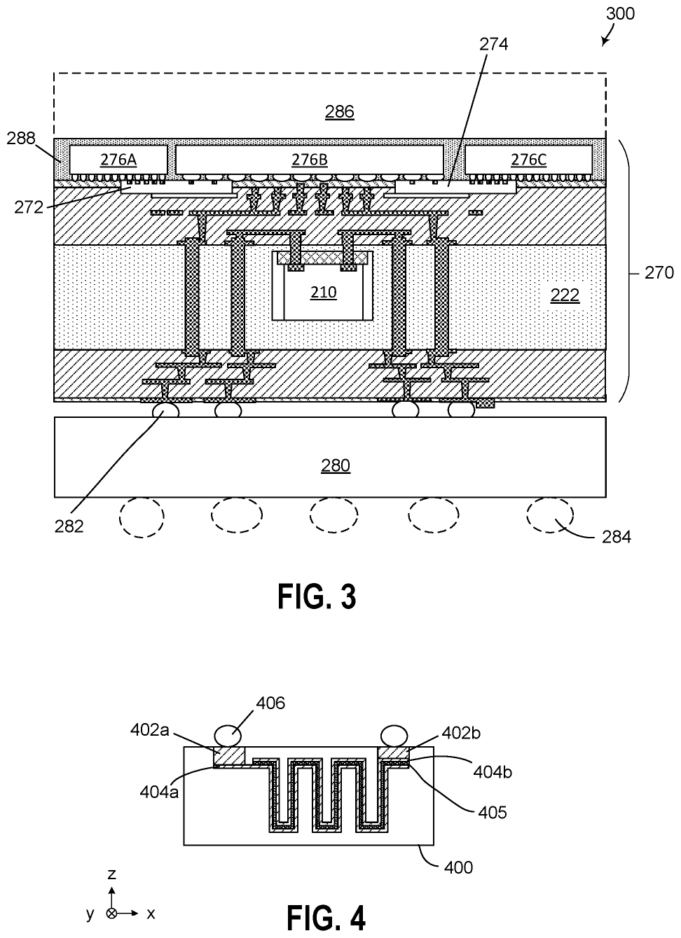

Returning to FIG. 1A, methods 101 complete at output 160 where the assembled device package structure is attached to any suitable host component. FIG. 3 illustrates an exemplary system 300 including one device package structure 270 attached to a host component 280 with interconnects 282, in accordance with some embodiments. In exemplary embodiments, interconnects 282 are solder (e.g., SAC) microbumps although other interconnect features are also possible. In some embodiments, host component 280 is predominantly silicon. Host component 280 may also comprise one or more alternative materials known to be suitable as interposers or package substrates (e.g., an epoxy preform, cored or coreless laminate board, etc.). Host component 280 may also include a printed circuit board (PCB). Host component 280 may include one or more metallized redistribution levels (not depicted) embedded within a dielectric material. Host component 280 may also include one or more IC die embedded therein.

While die 210 is shown in the example of FIG. 3 as being coupled with host component 280, in other examples, die 210 may be additionally or alternatively coupled with any of IC bridge die 272 and 274, or IC dies 276A, 276B, and 276C. It should be appreciated that the routing structures 256, 258 depicted in the figures are simplified representations and may omit metallization features 260 in order to not obscure principals of the embodiments disclosed herein.

Host component 280 may include interconnects 284 illustrated in dashed line. Interconnect 284 may comprise any solder (ball, bump, etc.) suitable for a given host board architecture (e.g., surface mount FR4, etc.). Also illustrated in dashed line, one or more heat spreaders and/or heat sinks 286 may be further coupled to device package structure 270, which may be advantageous, for example, where IC dies 276A, 276B, and 276C comprise one or more CPU cores or other circuitry of similar power density. Any package dielectric 288, such as a mold material, may surround sidewalls of IC dies 276A, 276B, and 276C. Although not illustrated, package dielectric 288 may be background so that heat spreader/sink 286 may be in closer contact with IC dies 276A, 276B, and 276C.

Embodiments that do not include a bond film are next described with reference to FIG. 5 to FIG. 7. As illustrated in FIG. 5, a variety of fabrication methods may be practiced to form IC device package structures having one or more of the features described herein. FIG. 5 illustrates a flow diagram of methods 501 for forming an IC device package structure including a die within a cavity in a substrate, the die having conductive features at a first side, and the substrate having a plurality of conductive vias extending between an exterior surface of the substrate and a first surface of the cavity, wherein the conductive features are coupled with the conductive vias by solder features, and a second side of the die is spaced away from a second surface of the cavity, in accordance with some embodiments. Methods 501 begin at input 510 where a workpiece including a first substrate is received. The workpiece may be prepared upstream of methods 501 and may be in a large panel format, a wafer format, or the like. In some embodiments, the first substrate comprises one or more organic materials, e.g., epoxy. The organic material(s) may include fillers, e.g., glass cloth or fibers. In some embodiments, the first substrate comprises glass. In embodiments in which the substrate comprises glass, the glass may be comprised of the same material as the first substrate 202, as described herein. The first substrate may be received with preformed features (e.g., through holes) formed in the substrate. Alternatively, the features may be fabricated with any process known to be suitable for the substrate material at 510. A two-sided hole formation process may entail laser ablation, a glass etch process (laser-assisted, or otherwise), or any other technique known to be suitable for forming holes in a glass substrate. In other examples, a two-sided hole formation process may include use of a mechanical tool, such as a drill, a laser, or any other technique known to be suitable for forming holes in organic materials, with or without fillers.

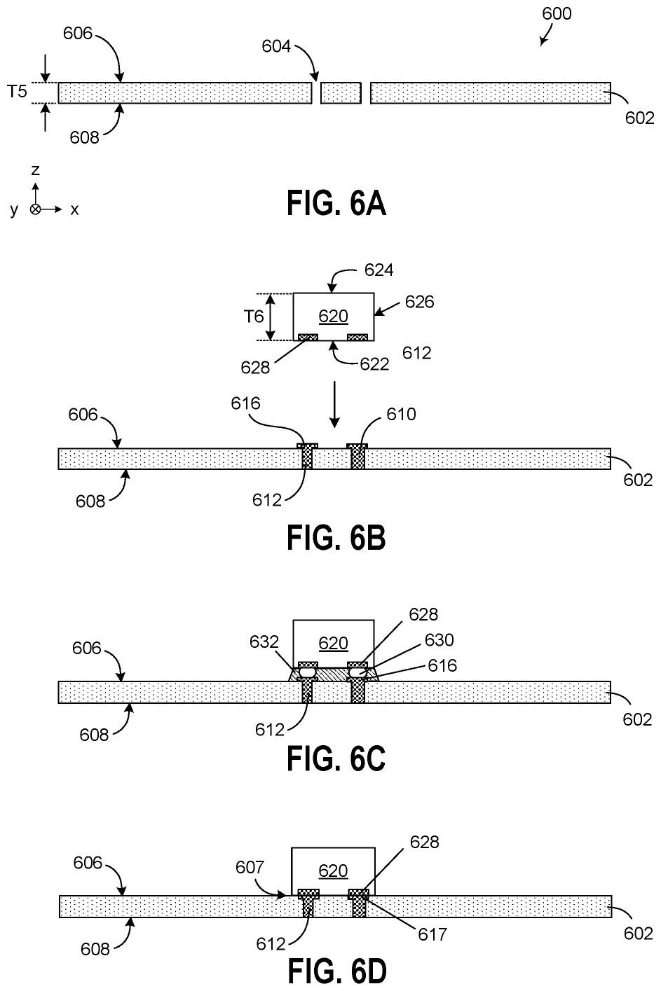

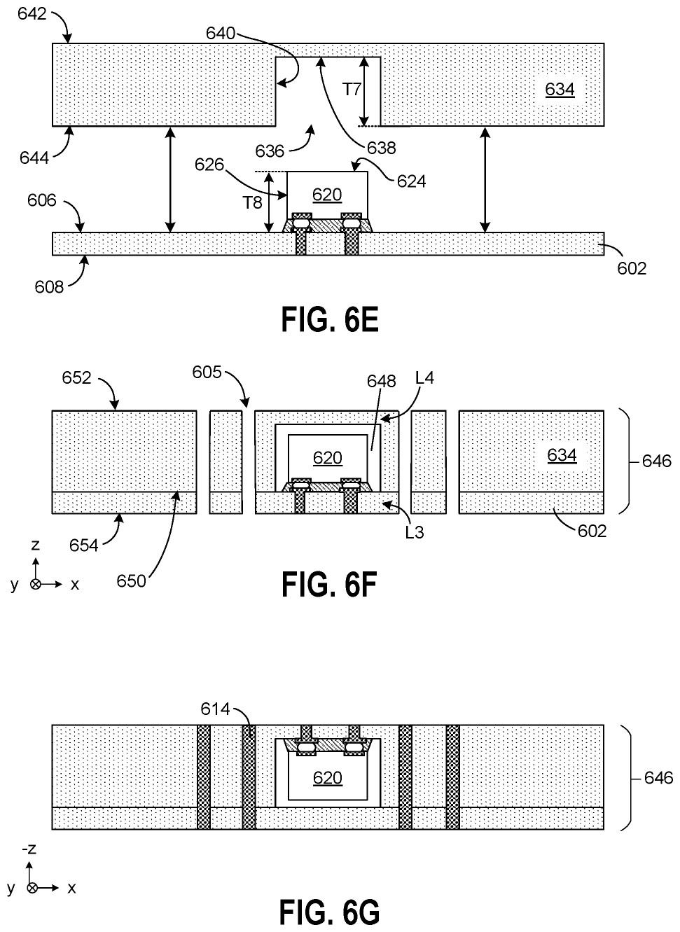

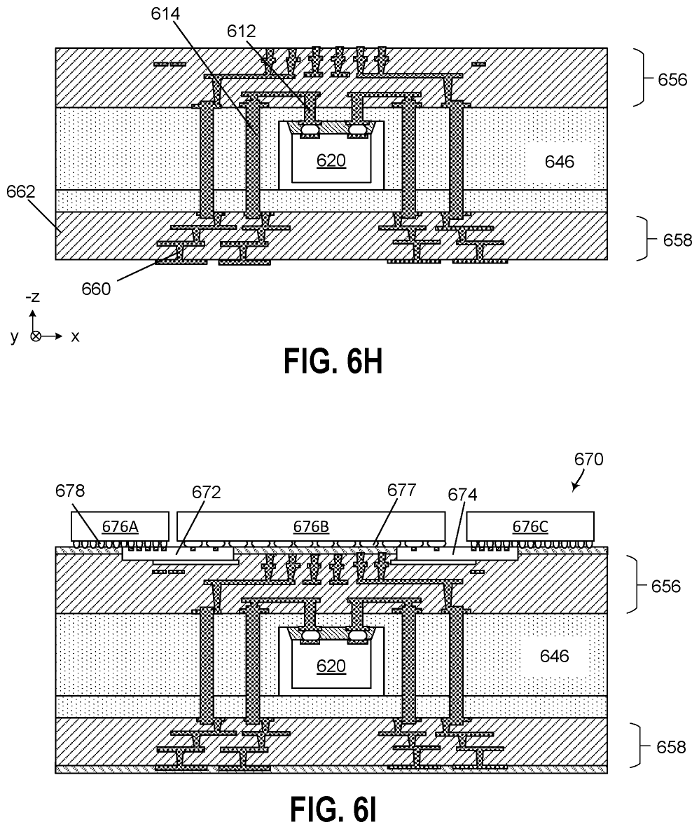

FIG. 6A is a cross-sectional view of an exemplary workpiece 600 including a fourth substrate 602. Fourth substrate 602 is a solid bulk material layer that may have been previously formed into any shape suitable for a packaging workpiece, such as rectangular. Fourth substrate 602 has a thickness T5 that may vary with implementation. In exemplary embodiments, thickness T1 is advantageously 100 μm to 2000 μm. The fourth substrate includes a first surface 606 and a second surface 608 opposite the first surface. A plurality of first holes 604 extend between the first surface 606 and the second surface 608.

Returning to FIG. 5, methods 501 continue at block 515 where a suitable metal is deposited within the holes in the fourth substrate to form electrically conductive vias. Operations at block 515 may include planarizing the via metallization to remove overburden associated with the plating process. Operations at block 515 may include forming pads or contacts on exterior surfaces of the substrate.

FIG. 6B is a cross-sectional view of workpiece 600 after a via metallization 610 has been deposited to form first vias 612, which extend through the substrate 602 between first surface 606 and second surface 608. First vias 612 may be referred to as through-substrate vias (TSVs) or, in some embodiments, through-glass vias (TGVs). As illustrated in FIG. 6B, the vias may include a pad or contact at a surface of the substrate. In particular, first vias 612 may include a pad or contact 616 at first surface 606. Contact 616 may extend above first surface 606, as shown in FIG. 6B, or may be flush with first surface 606, as shown in FIG. 6D as contact 617. Vias 612 may be formed by electroplating holes 604. In some examples, via metallization 610 is one or more metals (e.g., predominantly copper) deposited (e.g., electroplated) upon surfaces of the holes and substrate.

FIG. 6B also includes a cross-sectional view of a die 620 intended for attachment to substrate 602. As shown in FIG. 6B, die 620 comprises a first side 622 and a second side 624 opposite the first side. Die 620 has sidewalls 626 that extend between first side 622 and second side 624. Die 620 includes conductive features 628, e.g., metal pads or contacts, at first side 622. Die 620 has a thickness T6, which may be about 50 μm to about 2000 μm. In some embodiments, die thickness T6 is 300 μm to 600 μm. Die 620 may include deep trench capacitor in some embodiments. In some embodiments, die 620 may include any discrete component other than a capacitor, such as an inductor, resistor, transistor, diode, or optical switch. For example, the die 620 may be the same as or similar to die 400, as described herein.

Returning to FIG. 5, methods 501 continue at block 520 where one or more die are assembled to the workpiece and, more particularly, to interconnect structures coupled with conductive features 616 of first vias 612. At block 520, an underfill material may be introduced to encapsulate the interconnect structures and conductive features 616.

FIG. 6C is a cross-sectional view of workpiece 600 illustrating die 620 coupled with conductive features 616 of first vias 612 of fourth substrate 602. Conductive features 628 of die 620 may be electrically coupled with conductive features 616 through intervening electrical interconnects 630, which may comprise solder of any suitable composition. An underfill material 632 may be disposed around interconnects 630, and between die 620 and fourth substrate 602. The underfill material 632 may be an epoxy, and may include organic polymers and inorganic fillers. Any suitable method may be used to introduce and position the underfill material. In an embodiment, a capillary underfill process may be used to arrange the underfill material 632 into position.

In some embodiments, one or more die are assembled to the workpiece at block 520 using a bonding technique in which metal features embedded within an insulator of one IC die are directly fused to metal features embedded within an insulator of the substrate. Where both the metal features are fused, the resultant composite structure comprises a “hybrid bonded interface” of metallurgically interdiffused metals. A hybrid bonded interface may also include chemically bonded insulators. FIG. 6D is a cross-sectional view of workpiece 600 illustrating conductive features 628 of die 620 coupled with conductive features 617 of fourth substrate 602 at an interface 607.

Returning to FIG. 5, methods 501 continue at block 525 where a fifth substrate is aligned with the fourth substrate in preparation to be placed on and attached to the fourth substrate. The fifth substrate can be formed from an organic material or glass. In some embodiments, the fifth substrate is comprised of the same material as the fourth substrate. In some embodiments, the fourth substrate is comprised of a different material than the fourth substrate.

FIG. 6E is a cross-sectional view of workpiece 600 illustrating a fifth substrate 634 positioned over and aligned with fourth substrate 602. Fifth substrate 634 has a first surface 642 and a second surface 644. Fifth substrate 634 includes an open cavity 636, which has a depth T7. Recall that the height or thickness of die 620 is T6. In some embodiments, die 620 has a height T6 less than depth T7. In other embodiments, die 620 has a height T6 that is approximately equal to depth of cavity T7. As mentioned, in some embodiments, the height or thickness T6 of die 620 may be 300 μm to 600 μm. In some embodiments, depth T7 of cavity 636 may be at least 50 μm greater than die height T6. Cavity 636 includes a first surface 638 and sidewalls 640. Die 620 includes a first surface 624 and a second surface 624 opposite the first surface. An opening of the cavity 636 is at second surface 644. As illustrated in FIG. 6E, the second surface 644 of the first substrate faces first surface 606 of the fourth substrate 602. After die 620 is attached to fourth substrate 602 with electrical interconnects 630, the distance between second side 624 of die 620 and first surface 606 of the fourth substrate 602 is a height T8. The depth T7 that may be greater than height T8 in various embodiments. However, in some embodiments, cavity depth T7 may be substantially equal to height T8, provided T7 is greater than T8.

Returning to FIG. 5, methods 501 continue at block 530 where the first and second substrates are formed into a single substrate having a closed cavity, and holes are formed through the single substrate. At block 530, the first and second substrates are placed in contact with one another, and attached to one another. The first and second substrates may be attached in suitable manner known in the art. For example, a bonding film or other adhesive layer between the first and second substrates may be used to bond the two substrates together. Pressure, heat, or both pressure and heat may be used in conjunction with use of a bonding film or adhesive layer. In some examples, the bonding film or adhesive may be omitted, and pressure, heat, or both pressure and heat, alone may be used.

FIG. 6F is a cross-sectional view of workpiece 600 after the fifth substrate 634 has been placed onto, and fused or bonded with, fourth substrate 602. Fusing or bonding fourth and fifth substrates 602, 634 results in the formation of a single substrate 646 having a closed cavity 648. FIG. 6F also illustrates the workpiece 600 after second holes 605 have been formed through the single substrate 646 using any suitable method. In some embodiments, the single substrate 646 may have a seam 650 at the interface where the fourth and fifth substrates 602, 634 are fused or bonded together. After fifth substrate 634 is placed into position, die 620 may be spaced away from fifth substrate 634. Specifically, die 620 may be vertically spaced away from fifth substrate 634 such that the second side 624 of die 620 does not contact the first surface 638 of the cavity 636. In addition, die 620 may be laterally spaced away from fifth substrate 634 such that a sidewall 626 of die 620 does not contact a facing sidewall 640 of the cavity 636. For example, the difference between cavity depth T7 and attached die height T8 defines a distance between die second side 624 and cavity first surface 638. While not illustrated in FIG. 6F, in some embodiments, the first surface of the cavity may contact the second side of the die, or a cavity sidewall may contact a die sidewall. After the fourth and fifth substrates 602, 634 have been fused or bonded together, a first region may be defined between second side 624 of die 620 and first surface 638 of closed cavity 648. In addition, a second region may be defined between sidewall 626 of die 620 and a proximate sidewall 640 of closed cavity 648. In embodiments, these first and second regions comprise one or more gases, e.g., nitrogen, oxygen, argon, carbon dioxide, methane, nitrous oxide, ozone, etc. In some embodiments, the first and second regions comprise a vacuum. These regions may be referred to as an “air gap.”

Still referring to FIG. 6F, a third layer L3 of substrate 646 is between the first surface 606 of the fourth substrate 602 and second surface 654 of substrate 646 (which corresponds with second surface 608 of the fourth substrate 602). A fourth layer L4 of substrate 646 is between first surface 652 of substrate 646 ((corresponding with first surface 642 of fifth substrate 634) and first surface 638 of cavity 636. The third layer L3 may correspond with a portion of fourth substrate 602 proximate die 620. In some embodiments, die 620 is within the substrate 646 between the third layer L3 and fourth layer L4.

In some embodiments, after the fourth and fifth substrates 602, 634 have been fused or bonded together, there may be a seam 650 at the bonding interface, as the example in FIG. 6F illustrates. In other embodiments, seam 650 may be absent.

Returning to FIG. 1, methods 501 continue at block 535 where second vias may be formed in the second holes. FIG. 6G is a cross-sectional view of workpiece 600 after second vias 614 have been formed in second holes 605. Second vias 614 may be formed using electroplating methods. In some examples, via metallization is one or more metals (e.g., predominantly copper) deposited (e.g., electroplated) upon surfaces of the holes and substrate.

Returning to FIG. 1, methods 501 continue at block 540 where an electrical routing structure is built up over at least one side of the substrate prior to assembly with one or more IC die external to the substrate. The electrical routing structure may be electrically coupled to the vias and may, for example, comprise one or more levels of metallization features embedded within any suitable dielectric material. The electrical routing structure formed at block 540 may interconnect one or more IC die external to the substrate to each other and/or couple one or more of these IC die to the conductive vias. Moreover, the electrical routing structure formed at block 540 may interconnect one or more IC die external to the substrate to a die within a cavity in the substrate. Electrical routing structures may be formed on one or both exterior surfaces of the substrate.

FIG. 6H is a cross-sectional view of workpiece 600 after a routing structure 656 has been built-up over first surface 652 of substrate 646, and a routing structure 658 has been built-up over second surface 654. Routing structures 656, 658 comprise one or more levels of redistribution layer (RDL) metallization features 660 embedded within one or more layers of dielectric material 662. RDL metallization features 660 may comprise one or more metals, with one example being predominantly copper. At least some of RDL metallization features 660 are to electrically couple die 620 with circuitry elsewhere in the substrate or with an IC die coupled with the substrate in an IC device package.

Depending on the embodiment, dielectric material 662 may be any of a molding compound, a spin-on material, or dry film laminate material, for example. Dielectric material 662 may be introduced wet/uncured into a cast and then dried/cured. Alternatively, dielectric material 662 may be introduced as a semi-cured dry film that is fully cured following its application to substrate 646.

The composition of dielectric material 662 may vary with implementation. In some advantageous embodiments, dielectric material 662 is an organic dielectric, such as, an epoxy resin, phenolic-glass, or a resinous film such as the GX-series films commercially available from Ajinomoto Fine-Techno Co., Inc. (ABF). Dielectric material 662 may comprise epoxy resins (e.g., an acrylate of novolac such as epoxy phenol novolacs (EPN) or epoxy cresol novolacs (ECN)). In some specific examples, dielectric material 662 is a bisphenol-A epoxy resin, for example including epichlorohydrin. In other examples, dielectric material 662 includes aliphatic epoxy resin.

Returning to FIG. 1, methods 501 continue at block 545 where at least one IC die is assembled to the workpiece and, more particularly, to the electrical routing structure that was formed at block 535. IC die assembled at block 540 may each comprise any electrical circuitry, with one example being logic circuitry comprising logic gates. IC die assembled at block 545 may also comprise any photonic circuitry suitable for the detection, emission or processing (e.g., filtering, multiplexing and demultiplexing) of optical signals.

FIG. 6I is a cross-sectional view of an IC die package structure 670 after IC bridge die 672 and 674 are assembled to interconnect interfaces within a top metallization level of routing structure 656 of a co-packaged multi-die IC device package structure 670. In the example of FIG. 6I, IC die 676A, 676B, and 676C are assembled to interconnect interfaces within routing structure 656 and to the bridge IC die. IC bridge die 672 and 674 may be directly bonded to routing structure 256, or, electrically coupled through intervening electrical interconnects, which may comprise solder of any suitable composition. In the example illustrated in FIG. 6I, IC die 676A, 676B, and 676C may be electrically coupled to the IC bridge die through intervening electrical interconnects 677, 678, which may comprise solder of any suitable composition. IC die 676A, 676B, and 676C are each flip-chip attached with integrated circuitry within each die.

Each of IC die 676A, 676B, and 676C may be a fully functional ASIC, or may be a chiplet or tile that has more limited functionality supplementing the function of one or more other IC dies that are to be part of the same multi-die device. A chiplet or tile may, for example, be any of a wireless radio circuit, microprocessor core, electronic memory circuit, floating point gate array (FPGA), power management and/or power supply circuit, or include a MEMS device. In some examples, one or more of IC die 676A, 676B, and 676C include one or more banks of active repeater circuitry to improve multi-die interconnects (e.g., network-on-chip architectures). In other examples, one or more of IC die 676A, 676B, and 676C includes clock generator circuitry or temperature sensing circuitry. In other examples, one or more of IC die 676A, 676B, and 676C include logic circuitry that, along with other IC die 676A, 676B, and 676C implement multi-chiplet aggregated logic circuitry (e.g., mesh network-on-chip architectures). In some specific examples, at least one of IC die 676A, 676B, and 676C includes microprocessor core circuitry, for example comprising one or more shift registers.

IC die 676A, 676B, and 676C advantageously comprise field effect transistors (FETs) with a device pitch of 80 nm, or less. The FETs may be of any architecture (e.g., planar, non-planar, single-gate, multi-gate, stacked nanosheet, etc.). In some embodiments, FET terminals have a feature pitch of 20-40 nm. Additionally, or in the alternative, IC die 676A, 676B, and 676C may include active devices other than FETs. For example, IC die 676A, 676B, and 676C may include electronic memory structures, such as magnetic tunnel junctions (MTJs), capacitors, or the like.

IC die 676A, 676B, and 676C may comprise one or more IC die metallization levels embedded within an insulator. While the IC die metallization features may have any composition(s) of sufficient electrical conductivity, in exemplary embodiments, the IC die metallization features are predominantly copper (Cu). In other examples, the metallization features are predominantly other than Cu, such as, but not limited to predominantly Ru, or predominantly W. An uppermost one of the metallization features within IC die 676A, 676B, and 676C may have a feature pitch ranging from 100 nm to several microns, for example.

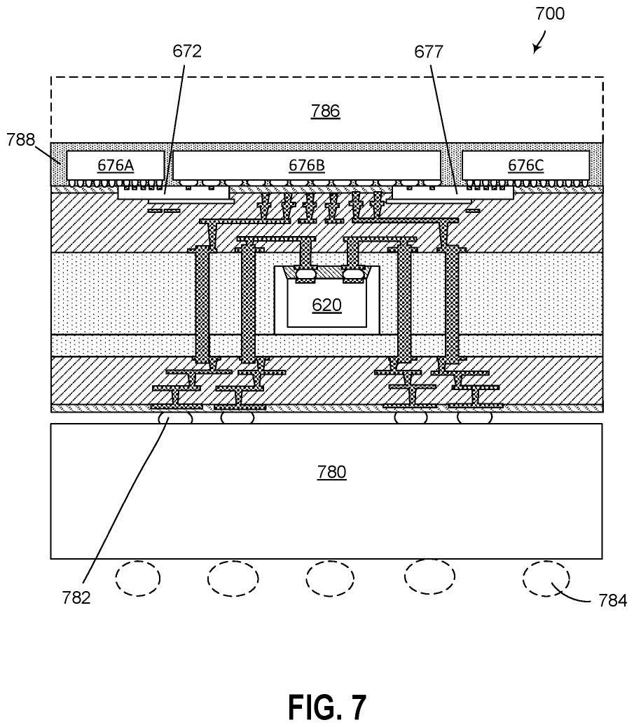

Returning to FIG. 5, methods 501 complete at output 550 where the assembled device package structure is attached to any suitable host component. FIG. 7 illustrates an exemplary system 700 including one device package structure 670 attached to a host component 780 with interconnects 782, in accordance with some embodiments. In exemplary embodiments, interconnects 782 are solder (e.g., SAC) microbumps although other interconnect features are also possible. In some embodiments, host component 780 is predominantly silicon. Host component 780 may also comprise one or more alternative materials known to be suitable as interposers or package substrates (e.g., an epoxy preform, cored or coreless laminate board, etc.). Host component 780 may also include a printed circuit board (PCB). Host component 780 may include one or more metallized redistribution levels (not depicted) embedded within a dielectric material. Host component 780 may also include one or more IC die embedded therein.

While die 620 is shown in the example of FIG. 7 as being coupled with host component 780, in other examples, die 620 may be additionally or alternatively coupled with any of IC bridge die 672 and 674, or IC dies 676A, 676B, and 676C. It should be appreciated that the routing structures 656, 658 depicted in the figures are simplified representations and may omit metallization features 660 in order to not obscure principals of the embodiments disclosed herein.

Host component 780 may include interconnects 784 illustrated in dashed line. Interconnect 784 may comprise any solder (ball, bump, etc.) suitable for a given host board architecture (e.g., surface mount FR4, etc.). Also illustrated in dashed line, one or more heat spreaders and/or heat sinks 786 may be further coupled to device package structure 670, which may be advantageous, for example, where IC dies 276A, 276B, and 276C comprise one or more CPU cores or other circuitry of similar power density. Any package dielectric 788, such as a mold material, may surround sidewalls of IC dies 276A, 276B, and 276C. Although not illustrated, package dielectric 288 may be background so that heat spreader/sink 286 may be in closer contact with IC dies 276A, 276B, and 276C.

FIG. 8 illustrates a mobile computing platform and a data server machine employing one or more IC device package structures, for example as described elsewhere herein. For example, mobile computing platform 805 or server machine 806 may include IC device package structure 270 or system 300. In another example, mobile computing platform 805 or server machine 806 may include IC device package structure 670 or system 700. Server machine 806 may be any commercial server, for example including any number of high-performance computing platforms disposed within a rack and networked together for electronic data processing. In an exemplary embodiment, server machine 806 includes a die within a cavity in a substrate, a bond film between the die and a surface of the cavity, and a plurality of self-aligned interconnects comprising a first portion through the substrate and a second portion through the bond film, as described elsewhere herein. In another exemplary embodiment, server machine 806 includes a die within a cavity in a substrate, the die having conductive features at a first side, and the substrate having a plurality of conductive vias extending between an exterior surface of the substrate and a first surface of the cavity, wherein the conductive features are coupled with the conductive vias by solder features, and a second side of the die is spaced away from a second surface of the cavity, as described elsewhere herein. The mobile computing platform 805 may be any portable device configured for each of electronic data display, electronic data processing, wireless electronic data transmission, or the like. For example, the mobile computing platform 805 may be any of a tablet, a smart phone, laptop computer, etc., and may include a display screen (e.g., a capacitive, inductive, resistive, or optical touchscreen), a chip-level or package-level integrated system 810, and a battery 815.

Whether disposed within the integrated system 810 illustrated in the expanded view 820, or as a stand-alone package within the server machine 806, the integrated system or server machine includes IC device package 270, system 300, IC device package 670, or system 700, as described elsewhere herein. System 300/700 may be further coupled to a host substrate 860, along with, one or more of a power management integrated circuit (PMIC) 830, RF (wireless) integrated circuit (RFIC) 825 including a wideband RF (wireless) transmitter and/or receiver (TX/RX) (e.g., including a digital baseband and an analog front-end module further comprises a power amplifier on a transmit path and a low noise amplifier on a receive path), and a controller 835. PMIC 830 may perform battery power regulation, DC-to-DC conversion, etc., and so has an input coupled to battery 815 and with an output providing a current supply to other functional modules. As further illustrated, in the exemplary embodiment, RFIC 825 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 4G, and beyond.

FIG. 9 is a functional block diagram of an electronic computing device 900, in accordance with an embodiment of the present invention. The computing device may include IC device package 270, system 300, IC device package 670, or system 700, as described elsewhere herein. Device 900 further includes a package substrate 902 hosting a number of components, such as, but not limited to, a processor 904 (e.g., an applications processor). Processor 904 may be physically and/or electrically coupled to package substrate 902. In some examples, processor 904 is within system 300/700, for example, as described elsewhere herein. Processor 904 may be implemented with circuitry in either or both of the host IC chip and chiplet. In general, the term “processor” or “microprocessor” may refer to any device or portion of a device that processes electronic data from registers and/or memory to transform that electronic data into other electronic data that may be further stored in registers and/or memory.

In various examples, one or more communication chips 906 may also be physically and/or electrically coupled to the package substrate 902. In further implementations, communication chips 906 may be part of processor 904. Depending on its applications, computing device 900 may include other components that may or may not be physically and electrically coupled to package substrate 902. These other components include, but are not limited to, volatile memory (e.g., DRAM 932), non-volatile memory (e.g., ROM 935), flash memory (e.g., NAND or NOR), magnetic memory (MRAM 930), a graphics processor 922, a digital signal processor, a crypto processor, a chipset 912, an antenna 925, touchscreen display 915, touchscreen controller 965, battery 916, audio codec, video codec, power amplifier 921, global positioning system (GPS) device 940, compass 945, accelerometer, gyroscope, speaker 920, camera 941, and mass storage device (such as hard disk drive, solid-state drive (SSD), compact disk (CD), digital versatile disk (DVD), and so forth), or the like. For example, processor 904 may be implemented within circuitry in IC die 276B or 676B, and an electronic memory (e.g., MRAM 930 or DRAM 932) may be implemented with circuitry in IC die 276A or 676A.

Communication chips 906 may enable wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 906 may implement any of a number of wireless standards or protocols. As discussed, computing device 900 may include a plurality of communication chips 906. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

Example 1: An apparatus comprising: a substrate comprising a first layer and a second layer, the first layer comprising a surface and an exterior surface opposite the surface; a die within the substrate between the first and second layers, the die comprising a plurality of conductive features at a side; a bond film between the surface and the side; and a plurality of conductive vias, each conductive via comprising a first portion through the substrate between the exterior surface and the surface, and a second portion through the bond film in contact with one of the conductive features and extending to the surface.

Example 2: The apparatus of example 1, wherein a center of the first portion is directly aligned with a center of the second portion.

Example 3: The apparatus of example 1, wherein: the first portion comprises a first opening in the substrate at the surface; and the second portion comprises a second opening in the bond film at the surface, and the first opening and the second opening are aligned, and the first opening comprises a shape that is substantially the same as a shape of the second opening.

Example 4: The apparatus of example 1 or example 2, wherein the surface is a first surface, and the side is a first side, wherein the substrate comprises a cavity between the first layer and the second layer; the second layer comprises a second surface facing the first surface; the die further comprises a second side opposite the first side, and the second surface contacts the second side.

Example 5: The apparatus of example 1 or example 2, wherein the surface is a first surface, and the side is a first side, wherein the substrate comprises a cavity between the first layer and the second layer; the second layer comprises a second surface facing the first surface; the cavity comprises a first sidewall between the first surface and the second surface; the die comprises a second side opposite the first side, and a second sidewall between the first side and the second side; and wherein the first sidewall is spaced away from the second sidewall.

Example 6: The apparatus of example 5, further comprising a region comprising a gas between the first sidewall and the second sidewall.

Example 7: The apparatus of example 1 or example 2, wherein the die comprises a capacitor.

Example 8: The apparatus of any of example 1, example 2, or example 7, wherein the substrate comprises an organic material or a glass.

Example 9: The apparatus of any of example 1 or example 2, or example 7 or example 8, wherein the exterior surface of the substrate is a first exterior surface, further comprising: a second exterior surface opposite the first exterior surface; an electrical routing structure on one of the first or second exterior surfaces, the electrical routing structure comprising metallization features and an organic dielectric material; and an integrated circuit (IC) die or a host component coupled to the electrical routing structure, wherein the plurality of conductive vias are coupled with the electrical routing structure to couple the die with one of the IC die or the host component.

Example 10: An apparatus, comprising: a substrate comprising a first layer and a second layer, the first layer comprising a first surface and a second surface opposite the first surface, the second layer comprising a third surface and fourth surface opposite the third surface; a die within the substrate between the first layer and the second layer, the die comprising a first side facing the first surface, a second side facing the third surface, and conductive features at the first side; and a plurality of conductive vias extending through the first layer between the first surface and the second surface; wherein: the conductive features are coupled with the conductive vias, and the second side is spaced away from the third surface.

Example 11: The apparatus of example 10, wherein the conductive features are coupled with the conductive vias by solder features.

Example 12: The apparatus of example 10 or example 11, further comprising a region comprising a dielectric material between the second side and the third surface wherein the dielectric material comprises a gas.

Example 13: The apparatus of any of examples 10 through 12, further comprising an underfill between the first surface and the first side of the die.

Example 14: The apparatus of example 10 or example 12, wherein the conductive features are coupled with the conductive vias by a hybrid bonded interface.

Example 15: The apparatus of any of examples 10 through 12, wherein: the substrate comprises a first sidewall between the first layer and the second layer; the die comprises a second sidewall between the first side and the second side; and the first sidewall is spaced away from the second sidewall, further comprising: a region comprising a gas between the first sidewall and the second sidewall.

Example 16: The apparatus of any of examples 10 through 12, or example 15, wherein the die comprises a deep trench capacitor.

Example 17: The apparatus of any of examples 10 through 12, or any of examples 15 through 16, wherein the second surface of the first layer is a first exterior surface, the fourth surface of the second layer is a second exterior surface, and the plurality of conductive vias are first conductive vias, further comprising: a first electrical routing structure on the first exterior surface, the first electrical routing structure comprising first metallization features and a first organic dielectric material; a second electrical routing structure on the second exterior surface, the second electrical routing structure comprising second metallization features and a second organic dielectric material; second conductive vias through the substrate to couple the first electrical routing structure and the second electrical routing structure; an integrated circuit (IC) die coupled to the first electrical routing structure; and a host component coupled to the second electrical routing structure; wherein the first conductive vias are coupled with the first electrical routing structure to couple the die with the IC die, or to couple the die with the host component via the first and second electrical routing structures.

Example 18: A method for fabricating an IC device structure, the method comprising: receiving a first substrate; attaching an IC die to the first substrate, the IC die comprising conductive features at a side of the IC die; attaching a second substrate to the first substrate to form a third substrate, the third substrate comprising an exterior surface and a cavity, the cavity comprising an interior surface opposite the exterior surface, wherein the IC die is within the cavity with the side facing the interior surface; and forming interconnects through the third substrate between the interior surface and the exterior surface, wherein the interconnects are coupled with the conductive features.

Example 19: The method of example 18, further comprising: providing a bond film between the interior surface of the cavity and the side of the IC die; and wherein: each interconnect comprises a first portion through the third substrate between the exterior surface and the interior surface, and a second portion through the bond film between one of the conductive features and the interior surface, wherein a center of the first portion is directly aligned with a center of the second portion.

Example 20: The method of example 18, wherein the side of the IC die is a first side, and the IC die comprises a second side opposite the first side, and wherein the interior surface is a first interior surface, and the cavity comprises a second interior surface opposite the first interior surface, further comprising: attaching the conductive features to the interconnects by solder features, wherein the second side is spaced away from the second interior surface.

However, the above embodiments are not limited in this regard, and, in various implementations, the above embodiments may include the undertaking of only a subset of such features, undertaking a different order of such features, undertaking a different combination of such features, and/or undertaking additional features than those features explicitly listed. The scope of the disclosure should therefore be determined with reference to the appended claims, along with the full scope of equivalents to which such claims are entitled.

What is claimed is:

1. An apparatus, comprising:
a substrate comprising a first layer and a second layer, the first layer comprising a surface and an exterior surface opposite the surface;
a die within the substrate between the first and second layers, the die comprising a plurality of conductive features at a side;
a bond film between the surface and the side; and
a plurality of conductive vias, each conductive via comprising a first portion through the substrate between the exterior surface and the surface, and a second portion through the bond film in contact with one of the conductive features and extending to the surface.

2. The apparatus of claim 1, wherein a center of the first portion is directly aligned with a center of the second portion.

3. The apparatus of claim 1, wherein:
the first portion comprises a first opening in the substrate at the surface; and
the second portion comprises a second opening in the bond film at the surface, and the first opening and the second opening are aligned, and the first opening comprises a shape that is substantially the same as a shape of the second opening.

4. The apparatus of claim 1, wherein the surface is a first surface, and the side is a first side, wherein the substrate comprises a cavity between the first layer and the second layer;
the second layer comprises a second surface facing the first surface;
the die further comprises a second side opposite the first side, and the second surface contacts the second side.

5. The apparatus of claim 1, wherein the surface is a first surface, and the side is a first side, wherein the substrate comprises a cavity between the first layer and the second layer;
the second layer comprises a second surface facing the first surface;
the cavity comprises a first sidewall between the first surface and the second surface;
the die comprises a second side opposite the first side, and a second sidewall between the first side and the second side; and;
wherein the first sidewall is spaced away from the second sidewall.

6. The apparatus of claim 5, further comprising a region comprising a gas between the first sidewall and the second sidewall.

7. The apparatus of claim 1, wherein the die comprises a capacitor.

8. The apparatus of claim 1, wherein the substrate comprises an organic material or a glass.

9. The apparatus of claim 1, wherein the exterior surface of the substrate is a first exterior surface, further comprising:
a second exterior surface opposite the first exterior surface;
an electrical routing structure on one of the first or second exterior surfaces, the electrical routing structure comprising metallization features and an organic dielectric material; and
an integrated circuit (IC) die or a host component coupled to the electrical routing structure, wherein the plurality of conductive vias are coupled with the electrical routing structure to couple the die with one of the IC die or the host component.

10. An apparatus, comprising:
a substrate comprising a first layer and a second layer, the first layer comprising a first surface and a second surface opposite the first surface, the second layer comprising a third surface and fourth surface opposite the third surface;
a die within the substrate between the first layer and the second layer, the die comprising a first side facing the first surface, a second side facing the third surface, and conductive features at the first side; and
a plurality of conductive vias extending through the first layer between the first surface and the second surface; wherein:
the conductive features are coupled with the conductive vias, and the second side is spaced away from the third surface.

11. The apparatus of claim 10, wherein the conductive features are coupled with the conductive vias by solder features.

12. The apparatus of claim 11, further comprising a region comprising a dielectric material between the second side and the third surface wherein the dielectric material comprises a gas.

13. The apparatus of claim 10, further comprising an underfill between the first surface and the first side of the die.

14. The apparatus of claim 10, wherein the conductive features are coupled with the conductive vias by a hybrid bonded interface.

15. The apparatus of claim 10, wherein:
the substrate comprises a first sidewall between the first layer and the second layer;
the die comprises a second sidewall between the first side and the second side; and
the first sidewall is spaced away from the second sidewall, further comprising:
a region comprising a gas between the first sidewall and the second sidewall.

16. The apparatus of claim 10, wherein the die comprises a deep trench capacitor.

17. The apparatus of claim 10, wherein the second surface of the first layer is a first exterior surface, the fourth surface of the second layer is a second exterior surface, and the plurality of conductive vias are first conductive vias, further comprising:
a first electrical routing structure on the first exterior surface, the first electrical routing structure comprising first metallization features and a first organic dielectric material;
a second electrical routing structure on the second exterior surface, the second electrical routing structure comprising second metallization features and a second organic dielectric material;
second conductive vias through the substrate to couple the first electrical routing structure and the second electrical routing structure;
an integrated circuit (IC) die coupled to the first electrical routing structure; and
a host component coupled to the second electrical routing structure; wherein the first conductive vias are coupled with the first electrical routing structure to couple the die with the IC die, or to couple the die with the host component via the first and second electrical routing structures.

18. A method for fabricating an IC device structure, the method comprising:
receiving a first substrate;
attaching an IC die to the first substrate, the IC die comprising conductive features at a side of the IC die;
attaching a second substrate to the first substrate to form a third substrate, the third substrate comprising an exterior surface and a cavity, the cavity comprising an interior surface opposite the exterior surface, wherein the IC die is within the cavity with the side facing the interior surface; and
forming interconnects through the third substrate between the interior surface and the exterior surface, wherein the interconnects are coupled with the conductive features.

19. The method of claim 18, further comprising:
providing a bond film between the interior surface of the cavity and the side of the IC die; and wherein:
each interconnect comprises a first portion through the third substrate between the exterior surface and the interior surface, and a second portion through the bond film between one of the conductive features and the interior surface, wherein a center of the first portion is directly aligned with a center of the second portion.

20. The method of claim 18, wherein the side of the IC die is a first side, and the IC die comprises a second side opposite the first side, and wherein the interior surface is a first interior surface, and the cavity comprises a second interior surface opposite the first interior surface, further comprising:
attaching the conductive features to the interconnects by solder features, wherein the second side is spaced away from the second interior surface.
